(19) United States
(12) Patent Application Publication
(10) Pub. No.: US 2017/0167023 A1
(43) Pub. Date: Jun. 15, 2017

(54) SILICON OR SILICON CARBIDE GAS INJECTOR FOR SUBSTRATE PROCESSING SYSTEMS

(71) Applicant: Lam Research Corporation, Fremont, CA (US)

(72) Inventors: Stephen Edward Proia, West Chester, OH (US); Jamie Burns, Fountain City, IN (US); Kevin Herzog, Eaton, OH (US); Karl Williams, Scotts Valley, CA (US)

(21) Appl. No.: 14/963,698

(22) Filed: Dec. 9, 2015

(51) Int. Cl. C23C 16/455

(52) U.S. Cl. CPC C23C 16/45563

(57) ABSTRACT

A gas injector includes a tubular rod segment that is made of a material selected from a group consisting of silicon and silicon carbide. The tubular rod segment includes a body defining a fluid passageway and threads machined directly on one end thereof. A knuckle includes threads. The threads of the tubular rod segment are connected to the threads of the knuckle. A gas supply tube is connected to the knuckle. One or more additional tubular rod segments can be attached by threads to the tubular rod segment to vary the length of the gas injector.

### FIELD

The present disclosure relates to substrate processing systems, and more particularly to gas injectors used to supply process gases to furnaces in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Batch processing of substrates such as semiconductor wafers in a furnace may be used during one or more stages of fabrication. Thermal chemical vapor deposition (CVD) or another process may be performed in the furnace. The substrates are heated to a predetermined temperature range and precursor gas is introduced into the furnace using a gas injector.

Gas injectors are typically made of either quartz or silicon carbide. In some circumstances, there may not be a sufficient match between a coefficient of thermal expansion (CTE) of a deposition film and the CTE of the materials used to make the gas injector. As a result, delamination of the film formed on inner surfaces of the gas injector may occur during operation. The delamination creates particles in the furnace. The particles may fall onto the substrates and increase defects. To prevent these defects, more frequent preventative maintenance is performed, which increases cost.

### SUMMARY

A gas injector includes a tubular rod segment that is made of a material selected from a group consisting of silicon and silicon carbide. The tubular rod segment includes a body defining a fluid passageway and threads machined directly on one end thereof. A knuckle includes threads. The threads of the tubular rod segment are connected to the threads of the knuckle. A gas supply tube is connected to the knuckle.

In other features, the tubular rod segment includes threads machined directly on an opposite end thereof. An additional tubular rod segment is connected to the threads on the opposite end of the tubular rod segment. The knuckle includes a body defining a cavity for receiving the tubular rod segments. The threads of the knuckle are located at one end of the cavity.

In other features, the knuckle includes first and second slots that extend from one end of the knuckle towards an opposite end of the knuckle. The tubular rod segment is made entirely of the material.

A gas injector includes a first tubular rod segment including a body defining a fluid passageway, male threads machined directly on one end of the first tubular rod segment, and female threads machined directly on an opposite end of the first tubular rod segment. A second tubular rod segment includes a body defining a fluid passageway, male threads machined directly on one end of the second tubular rod segment, and female threads machined directly on an opposite end of the second tubular rod segment. The first tubular rod segment and the second tubular rod segment are made of a material selected from a group consisting of silicon and silicon carbide. One end of the second tubular rod segment is threadably attached to one end of the first tubular rod segment. The fluid passageways of the first tubular rod segment and the second tubular rod segment are in fluid communication.

In other features, a third tubular rod segment includes a body defining a fluid passageway, male threads machined directly on one end of the third tubular rod segment, and female threads machined directly on an opposite end of the third tubular rod segment. One end of the third tubular rod segment is threadably attached to an opposite end of the second tubular rod segment. The third tubular rod segment is made of a material selected from a group consisting of silicon and silicon carbide. The fluid passageways of the third tubular rod segment and the second tubular rod segment are in fluid communication.

In other features, a knuckle is threadably attached to one of the first tubular rod segment and the second tubular rod segment. A gas supply tube is connected to the knuckle. The gas supply tube includes a fluid passageway in fluid communication with the fluid passageway of the one of the first tubular rod segment and the second tubular rod segment. The knuckle includes a body defining a cavity for receiving an outer diameter of the one of the first tubular rod segment and the second tubular rod segment.

In other features, the knuckle includes first and second slots that extend from one end of the knuckle towards an opposite end of the knuckle. The first tubular rod segment and the second tubular rod segment are made entirely of the material.

A gas injector includes N tubular rod segments that are entirely made of a material selected from a group consisting of silicon and silicon carbide. N is an integer greater than one. Each of the N tubular rod segments includes a body defining a fluid passageway and threads machined directly on opposite ends thereof. The N tubular rod segments are connected together by the threads. A knuckle is connected to the N tubular rod segments. A gas supply tube is connected to the knuckle.

In other features, the knuckle includes threads that are connected to the threads on one of the N tubular rod segments. The knuckle includes a body defining a cavity for receiving the one of the N tubular rod segments. The threads of the knuckle are located at one end of the cavity.

In other features, the knuckle includes first and second slots that extend from one end of the knuckle towards an opposite end of the knuckle.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of an example of a furnace including a gas injector according to the present disclosure;

FIG. 2 is a side assembly view of an example of a gas injector according to the present disclosure;

FIGS. 3 and 4 are side cross-sectional views of examples of male and female threads machined on ends of tubular rod segments of the gas injector;

FIGS. 5 and 6 are perspective views of an example of the gas injector according to the present disclosure;

FIGS. 7A and 7B are side and end cross-sectional views of an example of the connector and a knuckle according to the present disclosure;

FIG. 8 is a flowchart of a method for making the threaded tubular rod segments of the gas injector according to the present disclosure; and

FIG. 9 is a flowchart of a method for assembling the gas injector according to the present disclosure.

In the drawings, reference numbers may be reused to identify similar and/or identical elements.

### DETAILED DESCRIPTION

The present disclosure relates to a gas injector including multiple tubular rod segments. Each of the tubular rod segments has a cylindrical body and inner fluid passageway to allow for transport of process gases. In some examples, the tubular rod segments may be made entirely of silicon (Si) or silicon carbide (SiC), although other materials may be used.

Two or more of the tubular rod segments are connected together using mechanical threads to provide a variable length. The mechanical threads are machined directly into ends of the tubular rod segments. The threads eliminate the need for other types of attachment such as adhesive bonds. Once threaded together, the tubular rod segments form a single, integral gas injector tube that delivers process gases to the furnace or other substrate processing chamber.

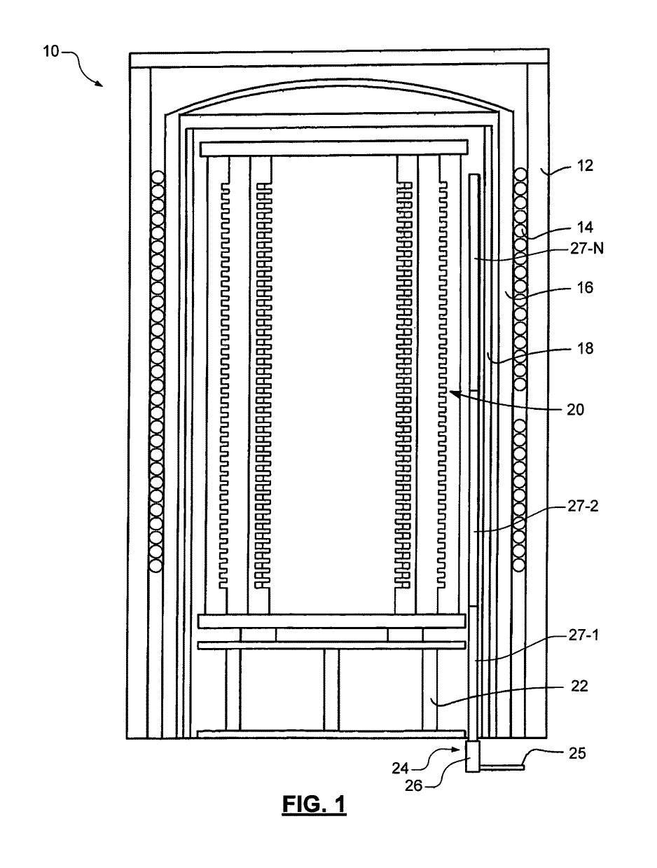

Referring now to FIG. 1, an example of a gas injector arranged in a furnace 10 is shown. While a specific type of furnace is shown, the gas injectors described herein may be used with other types of furnaces or other substrate processing equipment. The furnace 10 is shown to include a thermally-insulating outer housing 12. A heating coil 14 is arranged inside of the thermally-insulating outer housing 12. Power may be supplied to the heating coil 14 by a power supply (not shown).

An inner container 16 may be arranged inside of the thermally-insulating outer housing 12 and the heating coil 14. A liner 18 may be used, which fits within the inner container 16. A substrate support 20 sits on a pedestal 22. During processing, the pedestal 22 and substrate support 20 are generally surrounded by the liner 18. The substrate support 20 may include vertically arranged slots for holding multiple substrates during thermal processing. The substrates may be semiconductor wafers.

A gas injector 24 includes a supply tube 25, a knuckle 26 and multiple tubular rod segments 27-1, 27-2, . . . and 27-N (collectively tubular rod segments 27) (where N is an integer greater than one) that are threadably connected together. In some examples, the supply tube 25 is made of stainless steel, although other materials may be used. The gas injector 24 may be arranged between the substrate support 20 and the liner 18. The gas injector 24 includes an outlet on an upper end thereof for injecting processing gas within the liner 18.

A vacuum pump (not shown) may be used to evacuate process gases through a bottom portion of the inner container 16. The thermally-insulating outer housing 12, the inner container 16, and the liner 18 may be raised vertically to allow wafers to be transferred to and from the substrate support 20, although in some configurations these elements remain stationary while an elevator (not shown) raises and lowers the pedestal 22 and substrate support 20 into and out of the furnace 10.

Referring now to FIG. 2, the gas injector 24 is shown in further detail. The tubular rod segments 27 include male and female threads 40, 42 that are machined directly on ends thereof. For example, the tubular rod segment 27-1 includes the female threads 42 that mate with male threads 40 located on the adjacent tubular rod segment 27-2. Other tubular rod segments are connected in a similar manner to provide a variable length. The knuckle 26 includes female threads 42 on an upper end thereof that mates with the male threads 40 on the tubular rod segment 27-1. The supply tube 25 may be bonded, threaded or otherwise attached to a lower end of the knuckle 25.

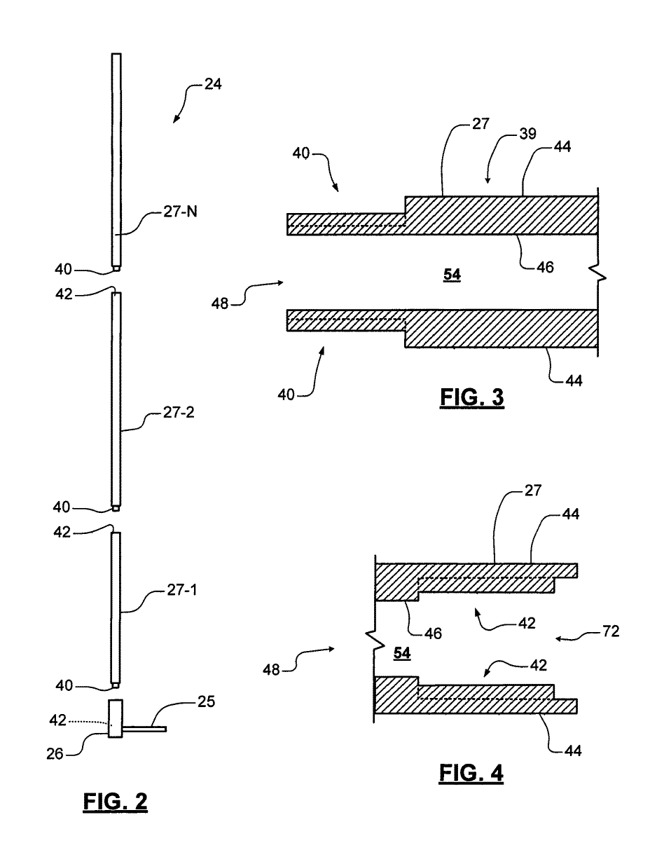

Referring now to FIG. 3, an example of the tubular rod segment 27 is shown in further detail. The tubular rod segment 27 includes a body 39. The male threads 40 are machined on an outer surface thereof. The tubular rod segment 27 has an outer diameter 44 and an inner diameter 46 defining a fluid passageway 54. The tubular rod segment 27 further includes a first opening 48 to the fluid passageway 54 that can act as a fluid inlet or outlet. A radially outer diameter of the male threads 40 may be spaced inwardly relative to the outer diameter 44 such that the male threads 40 are received inside of the corresponding female threads 42.

Referring now to FIG. 4, an example of the tubular rod segment 27 is shown in further detail. The tubular rod segment 27 includes the female threads 42 machined on an inner surface thereof. The tubular rod segment 27 further includes a second opening 72 to the fluid passageway 54 that can act as a fluid inlet or outlet.

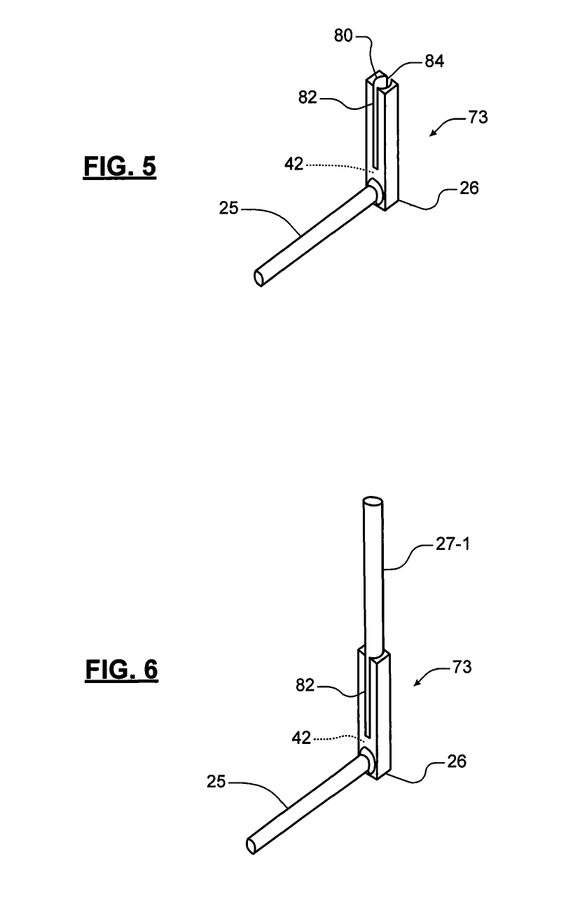

Referring now to FIGS. 5 to 7B, additional details relating to the knuckle 26 are shown. In FIG. 5, the knuckle 26 includes a body 73 defining a cavity 80 for receiving the tubular rod segment 27-1. The knuckle 26 includes slots 82 and 84 formed on opposite sides thereof that extend from an upper portion of the knuckle 26 to a point that is spaced from a bottom portion of the knuckle 26. The supply tube 25 is received at the bottom portion of the knuckle 26. In FIG. 6, the tubular rod segment 27-1 is inserted into the cavity 80 and the male threads 40 are received by the female threads 42 of the knuckle 26. The slots 82 and 84 provide physical support to the tubular rod segment 27-1 to increase structural strength and flexibility to reduce damage that may otherwise occur during temperature changes.

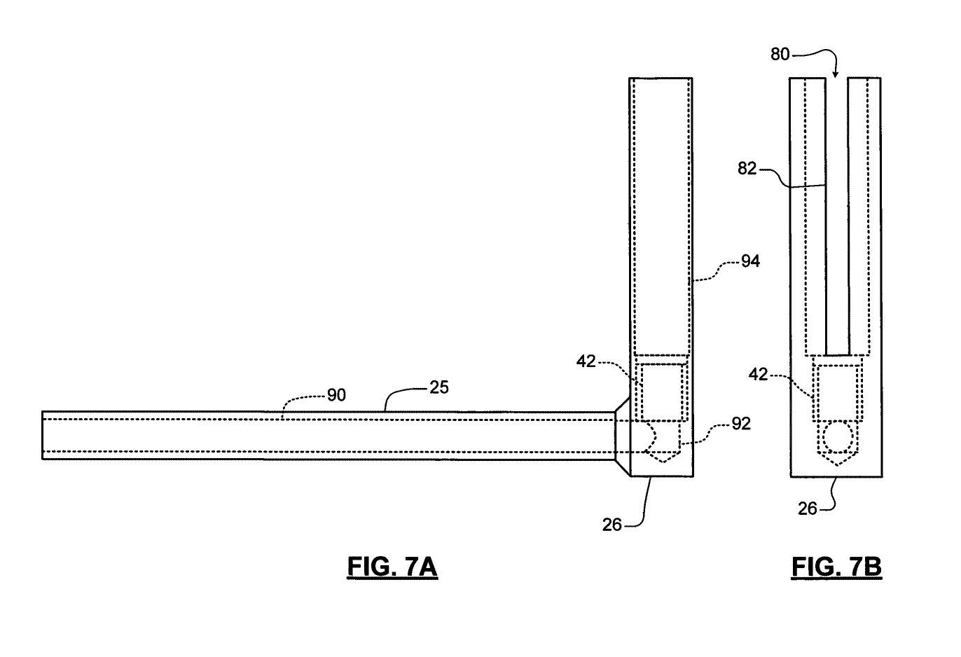

In FIGS. 7A and 7B, a fluid passageway 90 is defined through a center of the supply tube 25. A fluid passageway 92 in the knuckle 26 fluidly connects the fluid passageway 90 to the fluid passageway 54 of the tubular rod segment 27-1. An inner diameter 94 of the knuckle provides sufficient clearance to receive the outer diameter of the tubular member 27-1.

Referring now to FIG. 8, an example of a method 154 for making the gas injector is shown. At 152, a silicon ingot is grown. At 154, core drilling of the silicon ingot is performed to produce solid tubular rod segments. At 158, wire electrical discharge manufacturing (EDM) is performed on the solid tubular rod segments to obtain desired lengths and to smooth end faces of the tubular rod segments, although other methods may be used. At 162, EDM is also used to create the fluid passageways in the tubular rod segments, although other methods may be used.

At 164, computer numerical controlled (CNC) machining is performed on ends of the tubular rod segments to create the male and female threads, although other methods may be used. In some examples, a diamond tipped drill may be used. Lubrication such as water or oil-based lubricants may be used during CNC machining. Speed and feed settings are adjusted to optimize damage that may occur to the tubular rod segments with respect to time required to perform the CNC machining. In other examples, the threads are machined on the tubular rod segments using ductile mode machining as described in commonly-assigned “Ductile Mode Machining Methods for Hard and Brittle Components of Plasma Processing Apparatus”, U.S. Pat. No. 8,893,702, which issued on Nov. 25, 2014 and is hereby incorporated by reference in its entirety.

At 166, the tubular rod segments are cleaned. At 168, surface chemical treatment is performed on the tubular rod segments. At 170, the tubular rod segments are cleaned again after the surface chemical treatment. At 174, an additional cleaning step is performed as a final clean operation. For example only, hydrogen fluoride (HF) may be used.

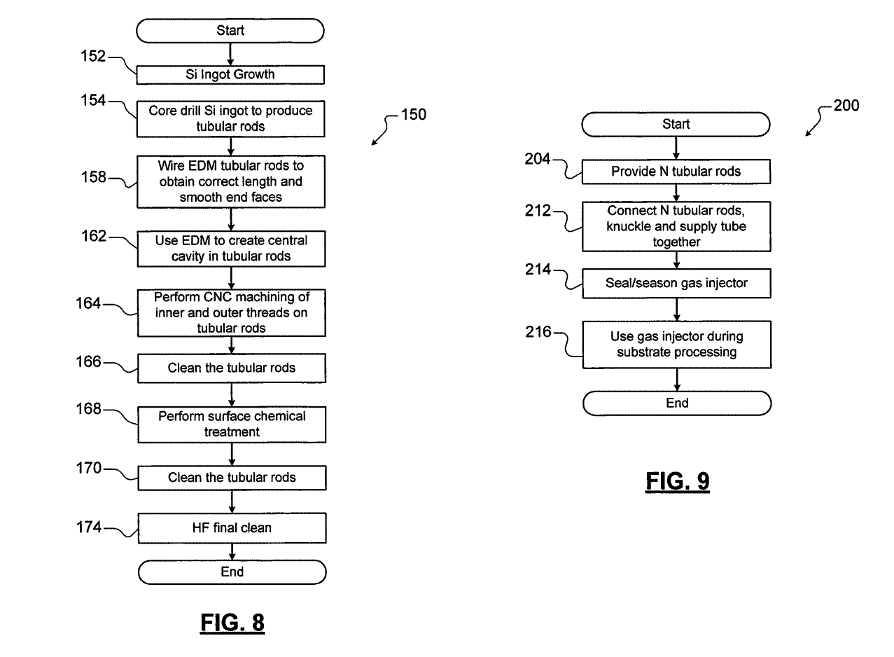

Referring now to FIG. 9, an example of a method 200 for assembling the gas injector is shown. At 204, the N tubular rod segments, the knuckle and the supply tube are provided, where N is an integer greater than or equal to one. At 212, the N rods are threaded together (when N is greater than one) and then threaded into the knuckle. The gas supply tube is connected to the knuckle. In some examples, the gas supply tube is connected using an adhesive, although other connection methods may be used. At 214, the gas injector may be sealed and seasoned prior to use. For example only, film may be deposited on inner portions of the gas injector to seal the gas injector. At 216, the gas injector is installed in a furnace and used in a process. In some examples, the gas injector is used during a thermal chemical vapor deposition (CVD) process such as the deposition of doped or undoped polysilicon, although other processes may be performed.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

What is claimed is:

1. A gas injector comprising:
a tubular rod segment that is made of a material selected from a group consisting of silicon and silicon carbide,
wherein the tubular rod segment includes a body defining a fluid passageway and threads machined directly on one end thereof;
a knuckle including threads, wherein the threads of the tubular rod segment are connected to the threads of the knuckle; and
a gas supply tube connected to the knuckle.

2. The gas injector of claim 1, wherein the tubular rod segment includes threads machined directly on an opposite end thereof.

3. The gas injector of claim 2, further comprising an additional tubular rod segment connected to the threads on the opposite end of the tubular rod segment.

4. The gas injector of claim 1, wherein the knuckle includes a body defining a cavity for receiving the tubular rod segments, wherein the threads of the knuckle are located at one end of the cavity.

5. The gas injector of claim 1, wherein the knuckle includes first and second slots that extend from one end of the knuckle towards an opposite end of the knuckle.

6. The gas injector of claim 1, wherein the tubular rod segment is made entirely of the material.

7. A gas injector comprising:
a first tubular rod segment including a body defining a fluid passageway, male threads machined directly on one end of the first tubular rod segment, and female threads machined directly on an opposite end of the first tubular rod segment; and
a second tubular rod segment including a body defining a fluid passageway, male threads machined directly on one end of the second tubular rod segment, and female threads machined directly on an opposite end of the second tubular rod segment,
wherein the first tubular rod segment and the second tubular rod segment are made of a material selected from a group consisting of silicon and silicon carbide,
wherein one end of the second tubular rod segment is threadably attached to one end of the first tubular rod segment, and
wherein the fluid passageways of the first tubular rod segment and the second tubular rod segment are in fluid communication.

8. The gas injector of claim 7, further comprising:
a third tubular rod segment including a body defining a fluid passageway, male threads machined directly on one end of the third tubular rod segment, and female threads machined directly on an opposite end of the third tubular rod segment,
wherein one end of the third tubular rod segment is threadably attached to an opposite end of the second tubular rod segment,
wherein the third tubular rod segment is made of a material selected from a group consisting of silicon and silicon carbide, and
wherein the fluid passageways of the third tubular rod segment and the second tubular rod segment are in fluid communication.

9. The gas injector of claim 7, further comprising a knuckle threadably attached to one of the first tubular rod segment and the second tubular rod segment.

10. The gas injector of claim 9, further comprising a gas supply tube connected to the knuckle, wherein the gas supply tube includes a fluid passageway in fluid communication with the fluid passageway of the one of the first tubular rod segment and the second tubular rod segment.

11. The gas injector of claim 10, wherein the knuckle includes a body defining a cavity for receiving an outer diameter of the one of the first tubular rod segment and the second tubular rod segment.

12. The gas injector of claim 11, wherein the knuckle includes first and second slots that extend from one end of the knuckle towards an opposite end of the knuckle.

13. The gas injector of claim 7, wherein the first tubular rod segment and the second tubular rod segment are made entirely of the material.

14. A gas injector comprising:
N tubular rod segments that are made entirely of a material selected from a group consisting of silicon and silicon carbide,
wherein N is an integer greater than one,
wherein each of the N tubular rod segments includes a body defining a fluid passageway and threads machined directly on opposite ends thereof, and
wherein the N tubular rod segments are connected together by the threads;
a knuckle connected to the N tubular rod segments; and
a gas supply tube connected to the knuckle.

15. The gas injector of claim 14, wherein the knuckle includes threads that are connected to the threads on one of the N tubular rod segments.

16. The gas injector of claim 15, wherein the knuckle includes a body defining a cavity for receiving the one of the N tubular rod segments, wherein the threads of the knuckle are located at one end of the cavity.

17. The gas injector of claim 14, wherein the knuckle includes first and second slots that extend from one end of the knuckle towards an opposite end of the knuckle.
